(19) United States
(12) Patent Application Publication
(10) Pub. No.: US 2026/0221344 A1
(43) Pub. Date: Jul. 30, 2026

(54) MODIFICATION OF CERAMIC CAPACITOR FOR MITIGATION OF DELAMINATION IN MEMORY DEVICES

(71) Applicant: Micron Technology, Inc., Boise, ID (US)

(72) Inventors: Yi-Yu Chen, Changhua City (TW); Yung-Sheng Zou, Taichung City (TW); Yi-Jing Chen, Taichung City (TW); Min-Hua Chung, Taichung City (TW); Chong Leong Gan, Penang (MY)

(21) Appl. No.: 19/037,740

(22) Filed: Jan. 27, 2025

(51) Int. Cl. H01L 23/00; H01G 4/30; H01L 25/065; H01L 25/16; H10B 80/00; H10D 1/68

(52) U.S. Cl. CPC H01G 4/30; H10B 80/00; H10D 1/682; H10W 90/00; H10W 72/01353; H10W 72/07311; H10W 72/07336; H10W 90/24; H10W 90/291; H10W 90/734; H10W 90/752; H10W 90/754

(57) ABSTRACT

An apparatus includes a ceramic capacitor comprising a ceramic component and one or more metal components; and an encapsulation layer that encapsulates the ceramic capacitor from an external environment, wherein at least one surface of the ceramic component of the ceramic capacitor is finished to strengthen a bond capability between the at least one surface and the encapsulation layer.

### TECHNICAL FIELD

Embodiments of the disclosure relate generally to memory sub-systems, and more specifically, relate to modification of ceramic capacitor for mitigation of delamination in memory devices.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various implementations of the disclosure.

FIG. 1 illustrates an example computing environment that includes a memory sub-system in accordance with some embodiments of the present disclosure.

FIGS. 2A and 2B illustrates example profile views of a surface mount device coupled to a substrate and encapsulated in an encapsulation material in accordance with some embodiments of present disclosure.

FIGS. 3A and 3B illustrate a modification method used to fabricate the modified ceramic capacitor by performing fluorinated plasma pre-treatment on the surface of the unmodified ceramic component of the capacitor in accordance with some embodiments of the present disclosure.

FIG. 4 is a flow diagram of an example method to implement the modified ceramic capacitor in a memory device by performing fluorinated plasma pre-treatment, in accordance with some embodiments of the present disclosure.

FIGS. 5A and 5B illustrate a modification method used to fabricate the modified ceramic capacitor by performing thin-film silica coating on the surface of the unmodified ceramic component of the capacitor in accordance with some embodiments of the present disclosure.

FIG. 6 is a flow diagram of an example method to implement the modified ceramic capacitor in a memory device by performing thin-film silica coating, in accordance with some embodiments of the present disclosure.

### DETAILED DESCRIPTION

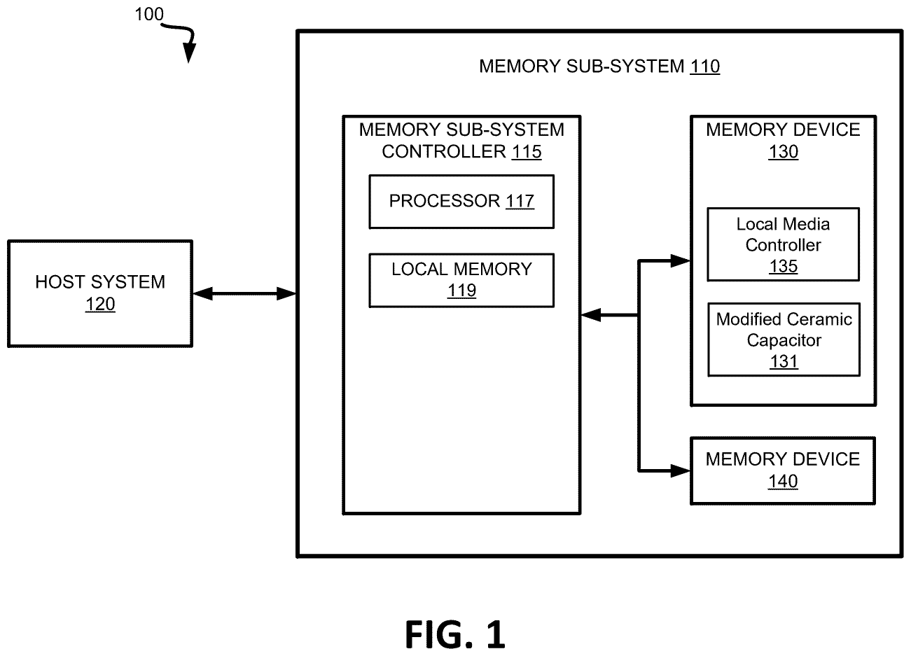

Aspects of the present disclosure are directed to modification of a ceramic capacitor for mitigation of delamination in a memory device of a memory sub-system. A memory sub-system can be a storage device, a memory module, or a hybrid of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. For example, negative-and (NAND) memory offers storage in the form of compact, high density configurations. A non-volatile memory device is a package of one or more dice, each including one or more planes. For some types of non-volatile memory devices (e.g., NAND memory), each plane includes of a set of physical blocks. Each block includes of a set of pages. Each page includes of a set of memory cells (“cells”). A cell is an electronic circuit that stores information. A block hereinafter refers to a unit of the memory device used to store data and can include a group of memory cells, a word line group, a word line, or individual memory cells. Each block can include a number of sub-blocks, where each sub-block is defined by an associated pillar (e.g., a vertical conductive trace) extending from a shared bit line. Memory pages (also referred to herein as “pages”) store one or more bits of binary data corresponding to data received from the host system.

Surface mount technology describes a process in which the electrical components or electrical circuits are mounted directly onto a surface of a circuit board, such as a substrate or printed circuit board (PCB). A surface mount device refers to an electrical component or electrical circuit mounted directly onto the surface of a circuit board (e.g., the terminals of a surface mount device are coupled to bond pads at a surface of the substrate or PCB). A surface mount device can have one or more terminals such as short pins or leads of various styles, flat contacts, an array of solder balls (e.g., ball grid array (BGA)), or terminations on the body of the device. A surface mount device can be an electrical component or electrical device contained within a package that has terminals that are exposed external to the package. The terminals can be electrically coupled to an electrical component or electrical circuit disposed within the package.

Some surface mount devices are mounted on a substrate and encapsulated using a material that adheres using an adhesive bond. For instance, the material that adheres using an adhesive bond can be a polymer such as epoxy mold compound (EMC). EMC includes epoxy and may consist of a polymer-based matrix, inorganic filler particles, and a wide range of (in)organic additives to fine-tune the properties. As the demand for complicated package design in memory devices continues to increase, the size of the surface mount device becomes smaller, which can cause the delamination between the surface mount device and the encapsulation material (e.g., EMC) to occur more often because of the weakness of the adhesive bonding.

Aspects of the present disclosure address the above and other deficiencies by implementing modification of a ceramic capacitor for mitigation of delamination in memory devices. The ceramic capacitor is a type of the surface mount device that can be encapsulated by an encapsulation material, such as EMC. A ceramic capacitor refers to a fixed-value capacitor where the ceramic material acts as the dielectric. In some cases, the ceramic capacitor can be constructed of two or more alternating layers of ceramic and a metal layer acting as the electrodes, which can be referred to as a multilayer ceramic capacitors (MLCC). The modified ceramic capacitor and the encapsulation material (e.g., in a form of layer - an encapsulation layer formed by the encapsulation material) may have a chemical reaction to prevent the delamination between them.

In some implementations, the modified ceramic capacitor is fabricated by performing fluorinated plasma pre-treatment on the surface of the unmodified ceramic component of the ceramic capacitor to strengthen a bond capability between the surface and the encapsulation layer. The fluorinated plasma pre-treatment may use a plasma of argon (Ar) and carbon tetrafluoride (CF₄) to treat the unmodified ceramic capacitor (e.g., unmodified ceramic component including barium titanate (BaTiO₃)) to form fluorinated functional groups on the surface of ceramic capacitor. The capacitor after the fluorinated plasma pre-treatment may be referred to as fluorinated ceramic capacitor (e.g., fluorinated ceramic component including fluorinated BaTiO₃). As such, the fluorinated ceramic capacitor and the encapsulation material may have a chemical reaction to prevent the delamination between them.

In some implementations, the modified ceramic capacitor is fabricated by performing thin-film silica coating on the surface of the unmodified ceramic component of the ceramic capacitor to strengthen a bond capability between the surface and the encapsulation layer. the thin-film silica coating may use a coating of silica (SiO₂) to treat the unmodified ceramic capacitor (e.g., unmodified ceramic component including barium titanate (BaTiO₃)) to form a thin film on the surface of ceramic capacitor. The capacitor after the thin-film silica coating may be referred to as coated ceramic capacitor (e.g., coated ceramic component including coated BaTiO₃). As such, the coated ceramic capacitor and the encapsulation material may have a chemical reaction to prevent the delamination between them.

Advantages of the present disclosure include preventing or reducing the delamination between the surface mount device, such as the ceramic capacitor, and the encapsulation material, such as EMC.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access the memory devices (e.g., memory devices 130) when the memory sub-system 110 is coupled with the host system 120 by the physical host interface (e.g., PCIe or CXL bus). The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include negative-and (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLCs) can store one bit per cell. Other types of memory cells, such as multi-level cells (MLCs), triple level cells (TLCs), quad-level (QLCs), and penta-level cells (PLCs) cells, can store multiple bits per cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion and a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory devices such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device combined with a local controller (e.g., local controller 135) for media management within the same memory device package. An example of a managed memory device is a managed NAND (MNAND) device.

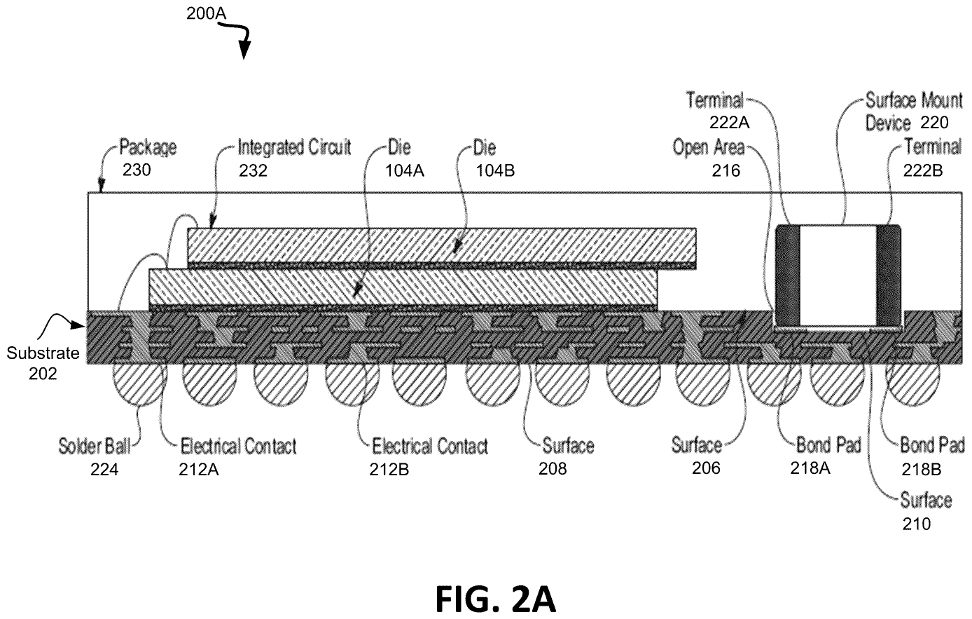

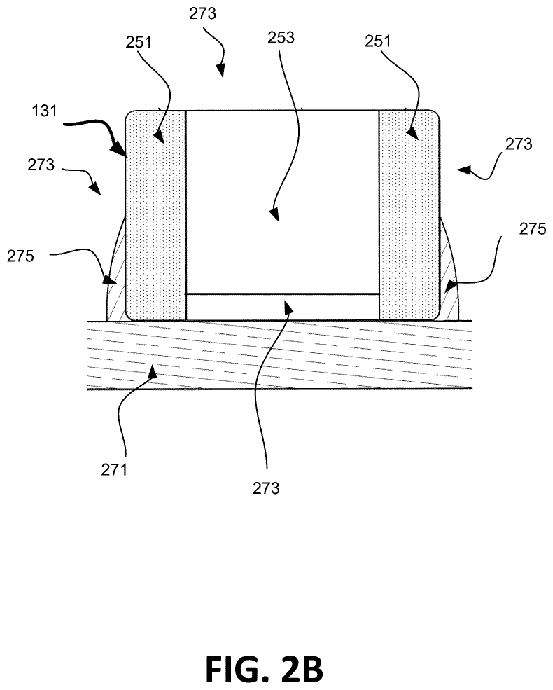

In some embodiments, the memory devices 130 includes a surface mount device, which may include a modified ceramic capacitor (e.g., modified multilayer ceramic capacitor (MLCC)) 131 coupled with a substrate. The details of the modified ceramic capacitor 131 are described with respect to FIGS. 2A-6.

FIG. 2A illustrates a profile view of a system 200A including a surface mount device 220 coupled to a substrate 202 and encased or encapsulated in an encapsulation material, such as a ceramic or plastic material (e.g., epoxy molding compounds), as illustrated by package 230, in accordance with some embodiments of the disclosure.

The system 200A may include integrated circuit 232 and surface mount device 220 that are disposed on a substrate 202. The integrated circuit 232 can include one or more integrated circuit dice. In some embodiments, the integrated circuit 232 may be a stacked integrated circuit, including integrated circuit die 204A and 204B (collectively referred to as “integrated circuit dice 204” herein). Integrated circuit dice 204 can include one or more types of integrated circuits. For example, system 200A can be a memory device that can include a logic die and one or more volatile or non-volatile memory dice. In some embodiments, integrated circuit die 204A can be a flip-chip that is directly bonded to the primary layer of the substrate 202. In some embodiments, one or more of the integrated circuit dice 204 can have one or more die pads. A die pad can be located at the surface, such as the top surface, of the respective integrated circuit dice 204. A die pad can be a surface area of an integrated circuit die that is designated for an external electrical contact (e.g., to electrically couple an integrated circuit die to another component). In some embodiments, the die pads are coated with a conductive material, such as gold or gold alloy. Conductive wires can couple the die pads to corresponding wire bond pads of the substrate 202.

The substrate 202 may be a multi-layer substrate, for example, including three or more layers, such as a primary layer, one or more inner layers, and a secondary layer. A primary layer can be the top-most layer above which one or more functional integrated circuit (IC) dice are stacked. The secondary layer can be the bottom-most layer of the substrate and include multiple electrical contacts that are coupled to another object, such as a PCB. The electrical contacts of the secondary layer couple the electronics mounted to the substrate to external signals. The one or more inner layers can be disposed between the primary layer and the secondary layer of the substrate. In some embodiments, one or more of the various layers of the substrate 202 can include a dielectric material (e.g., epoxy resin with glass fibers) that electrically insulate a layer from adjacent layers. In some embodiments, a layer can include conductive leads or traces on a dielectric material and conductive vias within a dielectric material of the layer that can electrically couple the conductive leads or traces of one layer to those of another layer. In some embodiments, one or more layers (or surface thereof) can be orientated approximately parallel to one another. Approximately parallel can refer to +/−10 degrees from absolute parallel or larger to take into account of manufacturing tolerances.

In some embodiments, the substrate 202 includes a surface 206 that is an external or top surface of substrate 202. In some embodiments, the substrate 202 can include one or more open areas, such as open area 216 that extend through the surface of the primary layer to an inner layer of the substrate 202. Open area 216 can expose a portion of the surface of the respective inner layer. The non-exposed surface of the respective inner layer can be bonded to the adjacent layer, such as the primary layer. In some embodiments, the secondary layer of the substrate 202 includes surface 208 that is an external surface of the substrate 202. In some embodiments, the secondary layer includes one or more electrical contacts, such as electrical contact 212A and electrical contact 212B (collectively referred to as “electrical contacts 212” herein). In some embodiments, the electrical contacts (e.g., electrical contacts 212) can be coupled (e.g., one or more of electrically or physically coupled) to a solder ball (e.g., solder ball 224), such as in a ball grid array as illustrated. In some embodiments, the electrical contacts can be configured, using conductive vias, to be electrically coupled to one or more of the adjacent layers, and to couple signals to and from the electrical contacts and the integrated circuit dice 204 or surface mount device 220.

In some embodiments, a portion of the surface of the inner layer is exposed through the open area in the primary layer. One or more bond pads, such as bond pad 218A and bond pad 218B (collectively referred to as “bond pads 218” herein) are disposed on the exposed portion(s) of the surface of the inner layer. A bond pad (e.g., component bond pad) can be a surface area of a substrate that is designated for an external electrical contact (e.g., to electrically couple the substrate to another component, such as a surface mount device) such as to a terminal of surface mount device 220. In some embodiments, a plating material, such as a nickel-gold alloy, is disposed above a bond pad to facility the formation of a solder joint between the bond pad and a component, such as a surface mount device. In some embodiments, one or more surface mount devices, such as surface mount device 220 can be directly coupled to respective bond pads (e.g., bond pads 218) of the inner layer. For example, surface mount device 220 can include one or more terminals, such as terminal 222A and terminal 222B (collectively referred to as “terminals 222” herein), that are coupled to bond pads 218A and 218B, respectively.

In some embodiments, surface mount device 220 can include any type of electrical component or electrical device. For example, surface mount devices can include active components, passive components, electromechanical components, quad-flat no-lead (QFN) components, among others. In some embodiments, the surface mount device 220 may be a passive component, such as a capacitor or resistor. In some embodiments, surface mount device 220 can be a modified ceramic capacitor, for example, a modified multilayer ceramic capacitor (MLCC).

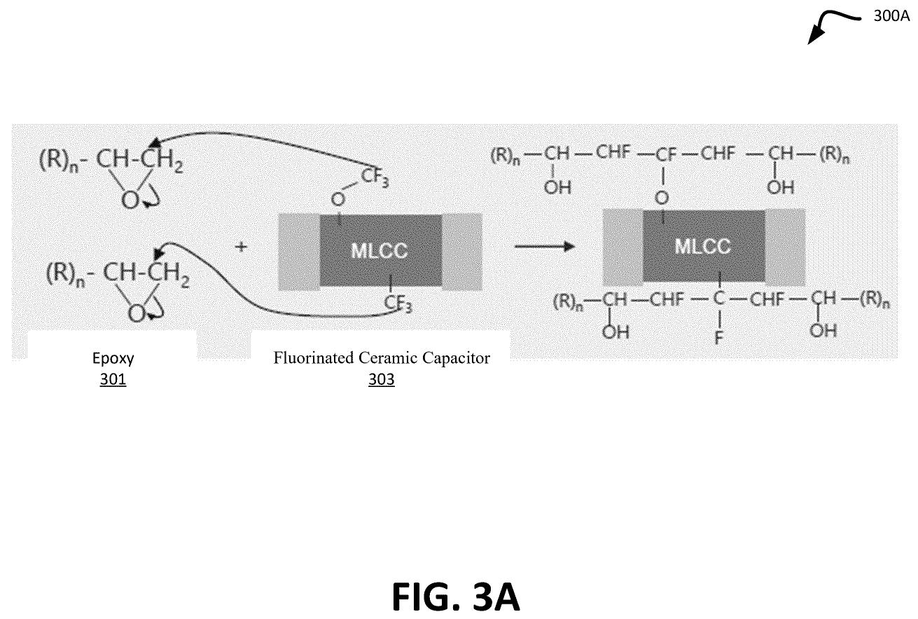

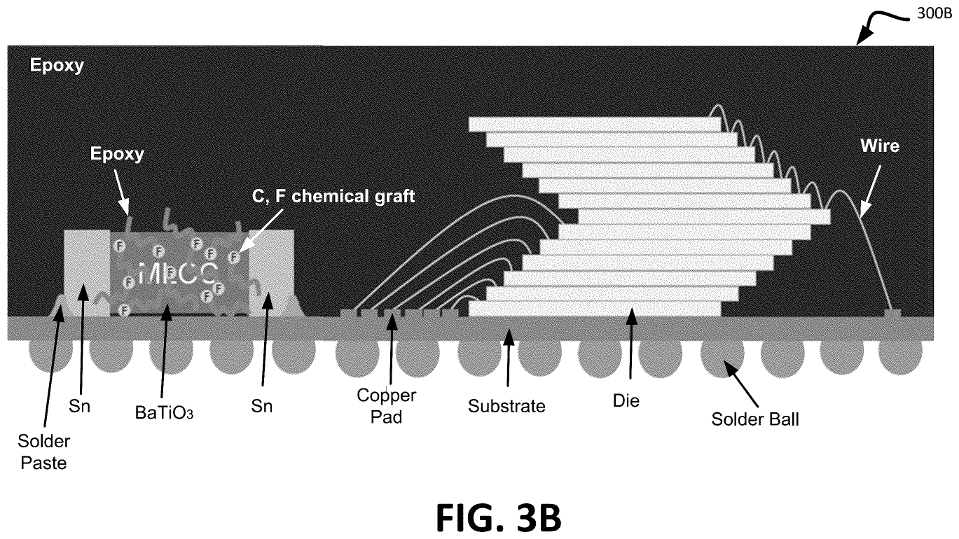

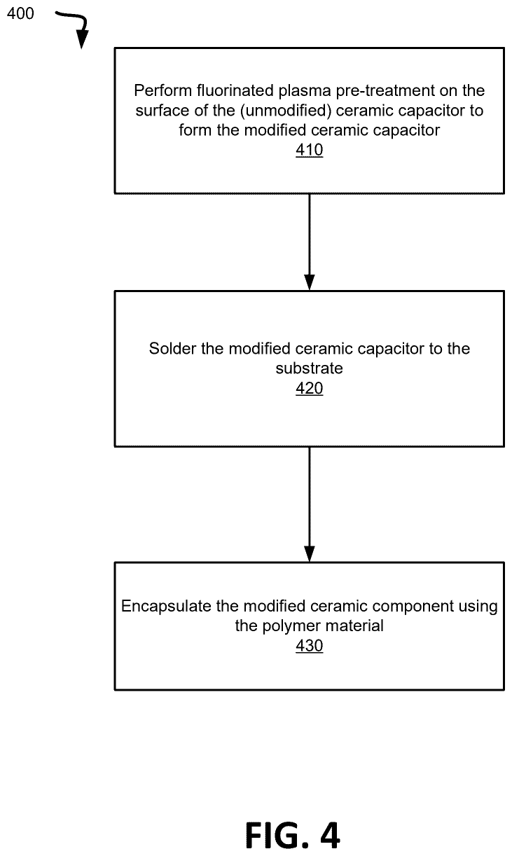

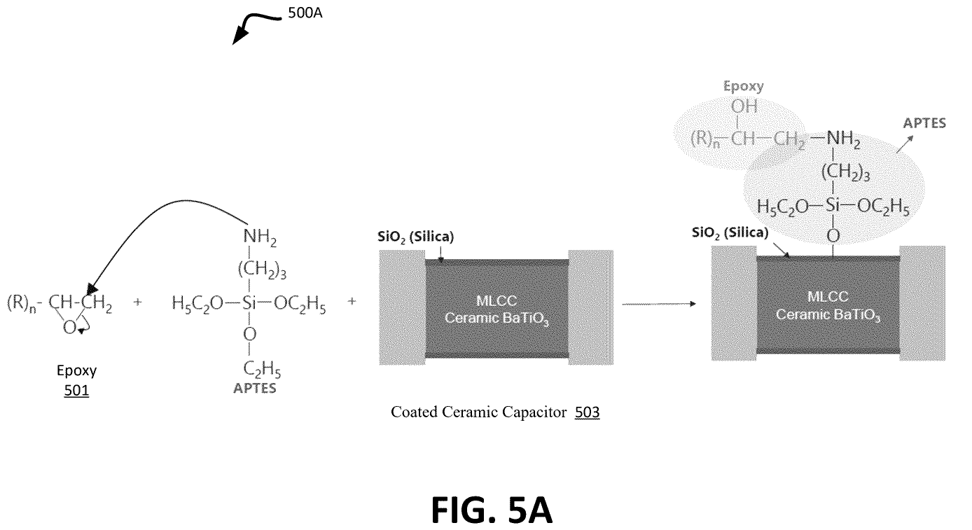

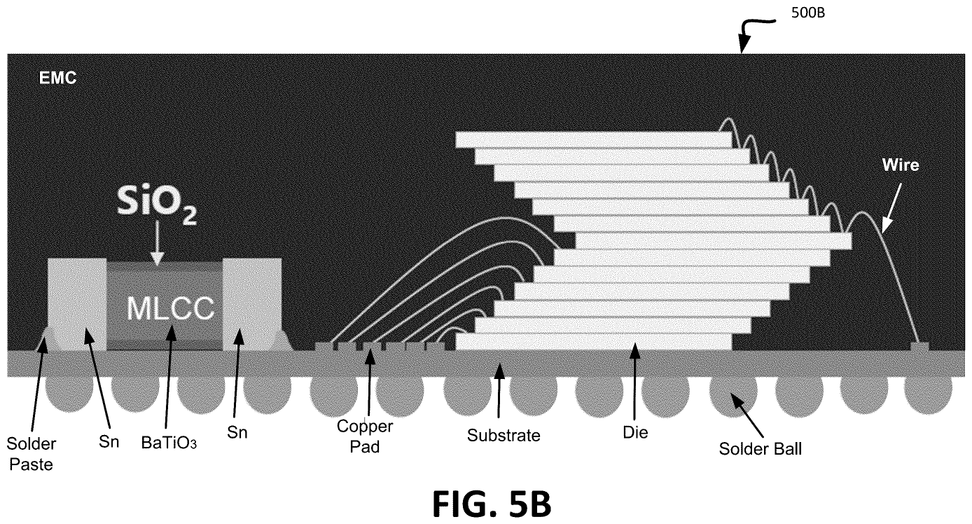

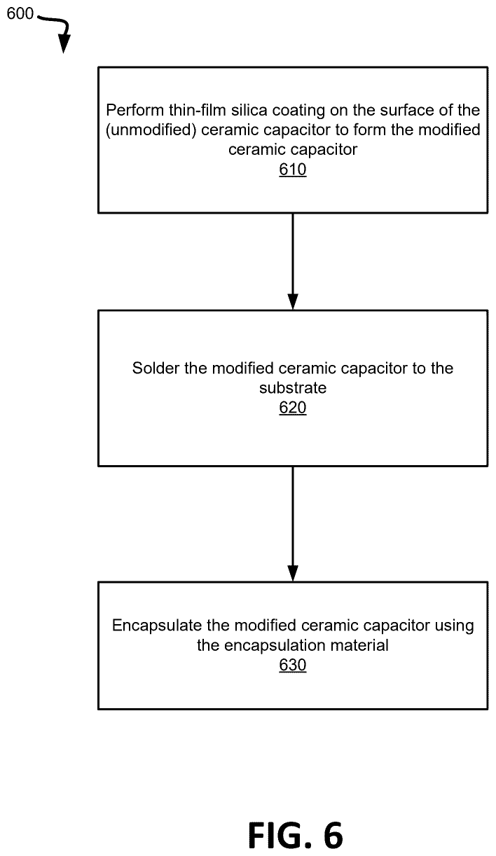

FIG. 2B illustrates a detailed profile view of a surface mount device coupled to a substrate, in accordance with some embodiments of the disclosure. In some implementations, the components of FIG. 2A can be considered to be part of system 200A of FIG. 2A. Referring to FIG. 2B, the surface mount device 220 can represent the modified ceramic capacitor 131. The modified ceramic capacity 131 includes one or more metal components 251 (e.g., Sn) and a modified ceramic component 253 (e.g., modified BaTiO₃, such as fluorinated BaTiO₃ or coated BaTiO₃ described below). The metal component 251 may act as the electrodes, and the modified ceramic component 253 may define the electrical behavior of the capacitor. In some implementations, the modified ceramic component 253 may comprise BaTiO₃ and other chemical components. The modified ceramic capacitor 131 may be mounted on the substrate 271 and encapsulated by the encapsulation material 273 (e.g., epoxy or EMC) and the solder paste 275 (e.g., mixture of metal solder powder and flux). In some implementations, the encapsulation material 273 may be in a form of a layer, and can refer to an encapsulation layer formed by the encapsulation material. Because the modified nature of the modified ceramic component 253, the bonding capability between the modified ceramic capacitor and the encapsulation material is increased compared with a bond capability between an unmodified ceramic capacitor and the encapsulation material. As such, the delamination between the modified ceramic component 253 and the encapsulation material 273 (e.g., the encapsulation layer formed by the encapsulation material) is reduced or eliminated. The modification details of the modified ceramic capacitor 131 are described with respect to FIG. 3A-3B, 4, 5A-5B, and 6. FIGS. 3A, 3B, and 4 illustrate one modification method used to fabricate the modified ceramic capacitor by performing fluorinated plasma pre-treatment on the surface of the unmodified ceramic component of the capacitor. FIGS. 5A, 5B, and 6 illustrate a modification method used to fabricate the modified ceramic capacitor by performing thin-film silica coating on the surface of the unmodified ceramic component of the capacitor. As such, the modified ceramic capacitor includes a ceramic component and one or more metal components, and at least one surface of the ceramic component of the ceramic capacitor is finished (e.g., by performing fluorinated plasma pre-treatment or thin-film silica coating on the surface of the unmodified ceramic component) to strengthen a bond capability between at least one surface and the encapsulation layer.

Referring to FIGS. 3A and 3B, the fluorinated plasma pre-treatment may use a plasma of argon (Ar) and carbon tetrafluoride (CF₄) to treat the unmodified ceramic capacitor (e.g., unmodified ceramic component including barium titanate (BaTiO₃)) to form fluorinated functional groups on the surface of ceramic capacitor. That is, at least one surface of the ceramic component of the ceramic capacitor is finished by performing a fluorinated plasma pre-treatment on a surface of an unmodified ceramic capacitor to strengthen a bond capability between at least one surface and the encapsulation layer. The capacitor after the fluorinated plasma pre-treatment may be referred to as fluorinated ceramic capacitor (e.g., fluorinated ceramic component including fluorinated BaTiO₃). As shown in FIG. 3A, the fluorinated ceramic capacitor 303 and epoxy 301 may have a chemical reaction to prevent the delamination between them. For example, the fluorination of BaTiO₃ has the chemical grafts of C, F ion on surface of BaTiO₃ that reacts with epoxy and strengthens cross-linking degree. The bonding of fluorinated BaTiO₃ is activated to link with the bonding of epoxy. FIG. 3B illustrates an example of the fluorinated ceramic capacitor is encapsulated by epoxy within the package 300B, which is similar to the package 230.

FIG. 4 is a flow diagram of an example method to implement the modified ceramic capacitor in a memory device by performing fluorinated plasma pre-treatment, in accordance with some embodiments of the present disclosure. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

Referring to FIG. 4, at operation 410, the processing logic may perform fluorinated plasma pre-treatment on the surface of the (unmodified) ceramic capacitor to form the modified ceramic capacitor. In some implementations, at least one surface of the ceramic component of the ceramic capacitor is finished by performing a fluorinated plasma pre-treatment on a surface of an unmodified ceramic capacitor to strengthen a bond capability between at least one surface and the encapsulation layer. In some implementations, the processing logic may place the (unmodified) ceramic capacitor (e.g., MLCC) in a gas flow of the plasma of argon (Ar) and carbon tetrafluoride (CF₄), which forms fluorinated functional groups on the surface of ceramic capacitor. In some implementations, the modified ceramic capacitor comprises a fluorinated ceramic component. In some implementations, the modified ceramic capacitor is fabricated by performing a fluorinated plasma pre-treatment on a surface of the unmodified ceramic capacitor.

At operation 420, the processing logic may solder the modified ceramic capacitor to the substrate. In some implementations, the processing logic may solder the modified ceramic capacitor to the substrate using the solder paste (e.g., mixture of metal solder powder and flux). In some implementations, the modified ceramic capacitor is mounted on the substrate. In some implementations, the modified ceramic capacitor comprises a first terminal and a second terminal, wherein the first terminal is coupled to a first component bond pad of the substrate, and wherein the second terminal is coupled to a second component bond pad of the substrate. In some implementations, the processing logic may perform a cleaning operation, for example, using a plasma of oxygen, to clean the modified ceramic capacitor (and the substrate) after soldering before encapsulation.

At operation 430, the processing logic may encapsulate the modified ceramic capacitor using the encapsulation layer, and the encapsulation layer is formed using an encapsulation material. In some implementations, the encapsulation material comprises an epoxy mold compound (EMC).

Referring to FIGS. 5A and 5B, the thin-film silica coating may use a coating of silica (SiO₂) to treat the unmodified ceramic capacitor (e.g., unmodified ceramic component including barium titanate (BaTiO₃)) to form a thin film on the surface of ceramic capacitor. That is, at least one surface of the ceramic component of the ceramic capacitor is finished by performing a thin-film silica coating on a surface of an unmodified ceramic capacitor to strengthen a bond capability between at least one surface and the encapsulation layer. The capacitor after the thin-film silica coating may be referred to as coated ceramic capacitor (e.g., coated ceramic component including coated BaTiO₃). As shown in FIG. 5A, the coated ceramic capacitor 503 and epoxy 501 may have a chemical reaction to prevent the delamination between them. For example, the silica thin film is coated on BaTiO3 as a middle layer between EMC (e.g., EMC may include epoxy and 3-Aminopropyl)triethoxysilane (APTES)) and unmodified ceramic component for preventing the delamination between EMC and ceramic component. The Si—O bond plays the chemical bonding function with BaTiO₃ and APTES silane agent added in EMC. FIG. 5B illustrates an example of the coated ceramic capacitor is encapsulated by EMC within the package 500B, which is similar to the package 230.

FIG. 6 is a flow diagram of an example method to implement the modified ceramic capacitor in a memory device by performing thin-film silica coating, in accordance with some embodiments of the present disclosure. The method 600 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

Referring to FIG. 6, at operation 610, the processing logic may perform thin-film silica coating on the surface of the (unmodified) ceramic capacitor to form the modified ceramic capacitor. In some implementations, at least one surface of the ceramic component of the ceramic capacitor is finished by performing a thin-film silica coating on a surface of an unmodified ceramic capacitor to strengthen a bond capability between at least one surface and the encapsulation layer. In some implementations, the processing logic may place the (unmodified) ceramic capacitor (e.g., MLCC) in a coating process of silica (SiO₂), which forms thin film of silica on the surface of ceramic capacitor. In some implementations, the modified ceramic capacitor comprises a coated ceramic component. In some implementations, the modified ceramic capacitor is fabricated by performing a thin-film silica coating on a surface of the unmodified ceramic capacitor.

At operation 620, the processing logic may solder the modified ceramic capacitor to the substrate. In some implementations, the processing logic may solder the modified ceramic capacitor to the substrate using the solder paste (e.g., mixture of metal solder powder and flux). In some implementations, the modified ceramic capacitor is mounted on the substrate. In some implementations, the modified ceramic capacitor comprises a first terminal and a second terminal, wherein the first terminal is coupled to a first component bond pad of the substrate, and wherein the second terminal is coupled to a second component bond pad of the substrate. In some implementations, the processing logic may perform a cleaning operation, for example, using a plasma of oxygen, to clean the modified ceramic capacitor (and the substrate) after soldering before encapsulation.

At operation 630, the processing logic may encapsulate the modified ceramic capacitor using the encapsulation layer, and the encapsulation layer is formed using an encapsulation material. In some implementations, the encapsulation material comprises an epoxy mold compound (EMC). In some implementations, EMC comprises epoxy and APTES.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. An apparatus, comprising:
a ceramic capacitor comprising a ceramic component and one or more metal components; and
an encapsulation layer that encapsulates the ceramic capacitor from an external environment, wherein at least one surface of the ceramic component of the ceramic capacitor is finished to strengthen a bond capability between the at least one surface and the encapsulation layer.

2. The apparatus of claim 1, wherein the ceramic capacitor comprises a multilayer ceramic capacitor (MLCC).

3. The apparatus of claim 1, wherein the encapsulation layer is formed using an encapsulation material, and wherein the encapsulation material comprises an epoxy mold compound (EMC).

4. The apparatus of claim 1, wherein the ceramic component comprises a fluorinated ceramic component.

5. The apparatus of claim 1, wherein the at least one surface of the ceramic component of the ceramic capacitor is finished by performing a fluorinated plasma pre-treatment on a surface of an unmodified ceramic capacitor.

6. The apparatus of claim 1, wherein the ceramic component comprises a coated ceramic component.

7. The apparatus of claim 1, wherein the at least one surface of the ceramic component of the ceramic capacitor is finished by performing a thin-film silica coating on a surface of an unmodified ceramic capacitor.

8. The apparatus of claim 1, further comprising:
a substrate, wherein the ceramic capacitor is mounted on the substrate.

9. The apparatus of claim 8, wherein the one or more metal components comprise a first terminal and a second terminal, wherein the first terminal is coupled to a first component bond pad of the substrate, and wherein the second terminal is coupled to a second component bond pad of the substrate.

10. A system comprising:
a substrate; and
a memory device, coupled to the substrate, comprising:
a ceramic capacitor comprising a ceramic component and one or more metal components; and
an encapsulation layer that encapsulates the ceramic capacitor from an external environment, wherein at least one surface of the ceramic component of the ceramic capacitor is finished to strengthen a bond capability between the at least one surface and the encapsulation layer.

11. The system of claim 10, wherein the ceramic capacitor comprises a multilayer ceramic capacitor (MLCC).

12. The system of claim 10, wherein the encapsulation layer is formed using an encapsulation material, and wherein the encapsulation material comprises an epoxy mold compound (EMC).

13. The system of claim 10, wherein the ceramic component comprises a fluorinated ceramic component.

14. The system of claim 10, wherein the at least one surface of the ceramic component of the ceramic capacitor is finished is fabricated by performing a fluorinated plasma pre-treatment on a surface of an unmodified ceramic capacitor.

15. The system of claim 10, wherein the ceramic component comprises a coated ceramic component.

16. The system of claim 10, wherein at least one surface of the ceramic component of the ceramic capacitor is finished by performing a thin-film silica coating on a surface of an unmodified ceramic capacitor.

17. The system of claim 10, wherein the one or more metal components comprise a first terminal and a second terminal, wherein the first terminal is coupled to a first component bond pad of the substrate, and wherein the second terminal is coupled to a second component bond pad of the substrate.

18. An apparatus, comprising:
a substrate;
a ceramic capacitor, wherein the ceramic capacitor is mounted on the substrate; and
an encapsulation layer that encapsulates the ceramic capacitor from an external environment, wherein at least one surface of the ceramic component of the ceramic capacitor is finished to strengthen a bond capability between the at least one surface and the encapsulation layer.

19. The apparatus of claim 18, wherein the ceramic component comprises a fluorinated ceramic component, and wherein at least one surface of the ceramic component of the ceramic capacitor is finished by performing a fluorinated plasma pre-treatment on a surface of an unmodified ceramic capacitor.

20. The apparatus of claim 18, wherein the ceramic component comprises a coated ceramic component, and wherein at least one surface of the ceramic component of the ceramic capacitor is finished by performing a thin-film silica coating on a surface of an unmodified ceramic capacitor.
